(19) United States
(12) Patent Application Publication
(10) Pub. No.: US 2018/0097519 A1
(43) Pub. Date: Apr. 5, 2018

(54) ADAPTIVE LEVEL SHIFTER

(71) Applicant: TAIWAN SEMICONDUCTOR MANUFACTURING COMPANY LTD., HSINCHU (TW)

(72) Inventors: YUNG-CHOW PENG, HSINCHU CITY (TW); MAO-HSUAN CHOU, HSINCHU COUNTY (TW)

(21) Appl. No.: 15/282,342

(22) Filed: Sep. 30, 2016

(51) Int. Cl. H03K 19/00; H03K 19/0185

(52) U.S. Cl. CPC H03K 19/0013; H03K 19/018521

(57) ABSTRACT

A level shifter operating between a first power domain under a first supply voltage and a second power domain under a second supply voltage is provided. The level shifter includes a latch, formed by a first transistor and a second transistor, configured to store data and operate in the second power domain. The level shifter further includes a third transistor configured to be biased at the first supply voltage, and a current source configured to generate a current in response to the first supply voltage. The current flows towards the latch, and the magnitude of the current is positively correlated with the first supply voltage. In response to a first asserted state of the first supply voltage, the third transistor dominates over the current source in toggling the data and, in response to a second asserted state of the first supply voltage, the current source dominates over the third transistor in toggling the data. The second asserted state is lower in voltage level than the first asserted state.

### BACKGROUND

In a multiple-VDD design, different blocks such as core circuits or input/output (I/O) circuits may operate at different voltages. A level shifter is used to convert one voltage level of a signal to another voltage level when the signal passes from one power domain to another power domain, for example, from a low power domain to a high power domain. A level shifter will amplify the signal for that power domain so that cells in the high power domain can read a logic-1 or logic-0 correctly. With the increasing demand for low power circuit designs, it has been a topic of interest to develop level shifters for converting a relatively low supply voltage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of an adaptive level shifter in accordance with an embodiment.

FIG. 2 is a circuit diagram of an adaptive level shifter in accordance with another embodiment.

FIG. 3 is a circuit diagram of an adaptive level shifter in accordance with still another embodiment.

FIG. 4 is a diagram illustrating simulation results.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

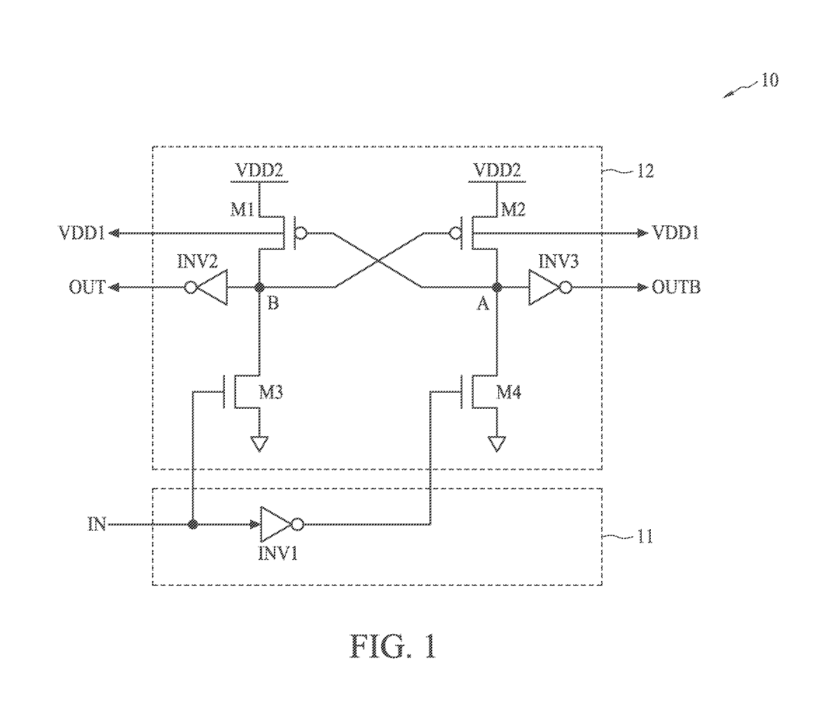

FIG. 1 is a circuit diagram of an adaptive level shifter 10 in accordance with an embodiment. Referring to FIG. 1, the adaptive level shifter 10 includes a first transistor M1, a second transistor M2, a third transistor M3, a fourth transistor M4, a first inverter INV1, a second inverter INV2 and a third inverter INV3. The first inverter INV1 operates in a first power domain 11, which works under a first supply voltage VDD1, and the transistors M1 to M4 and the inverters INV2 and INV3 operate in a second power domain 12, which works under a second supply voltage VDD2. In the present example, the adaptive level shifter 10 converts an input signal IN in the first power domain 11 to output signals OUT and OUTB in the second power domain 12. Moreover, the voltage level of VDD2 is larger than that of VDD1. For example, VDD1 may range from approximately 0.3 volt (V) to 0.7V, while VDD2 may range from approximately 0.8V to 1.8V, depending on circuit designs. Furthermore, the voltage difference between VDD2 and VDD1 is smaller than the threshold voltage of the PMOS transistor M1 or M2, which may be approximately 0.4V to 0.6V in amplitude.

The first transistor M1, a p-type metal-oxide-semiconductor (PMOS) transistor, includes a source terminal to receive a supply voltage VDD2, a drain terminal connected to an input of the second inverter INV2, and a gate terminal connected to an input of the third inverter INV3. In addition, the first transistor M1 includes a bulk or body terminal (not numbered) connected to a supply voltage VDD1, which would otherwise be connected to the supply voltage VDD2 in existing level shifters. The source and drain terminals of a transistor may be interchangeable, depending on the voltage level they receive. Function of the bulk terminal which receives a supply voltage VDD1 from the first power domain 11 rather than be connected to VDD2 will be further discussed in detail.

The second transistor M2, also a PMOS transistor, includes a source terminal to receive the supply voltage VDD2, a drain terminal connected to the input of the third inverter INV3 and also to the gate terminal of the first transistor M1, and a gate terminal connected to the input of the second inverter INV2 and also to the drain terminal of the first transistor M1. In addition, similar to the first transistor M1, the second transistor M2 includes a bulk terminal (not numbered) connected to the power supply VDD1, which would otherwise be connected to the supply voltage VDD2 in existing level shifters.

The third transistor M3, an n-type metal-oxide-semiconductor (NMOS) transistor, includes a drain terminal connected to the input of the second inverter INV2 and also to the drain terminal of the first transistor M1, a source terminal connected to a reference voltage level, and a gate terminal connected to an input of the first inverter INV1.

The fourth transistor M4, also an NMOS transistor, includes a drain terminal connected to the input of the third inverter INV3 and also to the drain terminal of the second transistor M2, a source terminal connected to a reference voltage level, and a gate terminal connected to an output of the first inverter INV1.

The first inverter INV1 includes an input configured to receive the input signal IN and connected to the gate terminal of the third transistor M3. Furthermore, the first inverter INV1 includes an output connected to the gate terminal of the fourth transistor M4.

The second inverter INV2 includes an input connected to the drain terminals of the first and third transistors M1, M3 and to the gate terminal of the second transistor M2. Moreover, the second inverter INV2 includes an output at which the output signal OUT is provided.

The third inverter INV3 includes an input connected to the drain terminals of the second and fourth transistors M2, M4 and to the gate terminal of the first transistor M1. Moreover, the third inverter INV3 includes an output at which the output signal OUTB is provided. The voltage levels of the output signals OUT and OUTB are complementary to each other. For example, when the output signal OUT has a high logic level “1” or is logically high, the output signal has a low logic level “0” or is logically low.

The transistors M1 to M4 and inverters INV1 to INV3 constitute a level shifter. The adaptive level shifter 10 may include other forms or structures of a level shifter and is not limited to the specific level shifter as illustrated in the embodiment of FIG. 1. In existing level shifters, the bulk terminals of first and second transistors M1 and M2 are connected to their respective source terminals, which in turn are connected to the supply power VDD2. Such mechanism ensures that the source to bulk voltage, or Vsb, is zero and therefor avoids the body effect. The body effect, or called the “back-gate effect,” refers to the change in the threshold voltage by an amount approximately equal to the change in the source to bulk voltage in a transistor. When the bulk is not connected to source, the threshold voltage increases.

In operation, in response to a logically low input signal IN, the third transistor M3 is turned off and the fourth transistor M4 is turned on. As the fourth transistor M4 is turned on, the input of the third inverter INV3, or node A, is pulled down to ground. Consequently, the output signal OUTB is logically high, or VDD2. Moreover, the low logic level at node A turns on the first transistor M1. As the first transistor M1 is turned on, the input of the second inverter INV2, or node B, is pulled up to VDD2. As a result, the output signal OUT is logically low.

Further, in response to a logically high input signal IN, the third transistor M3 is turned on and the fourth transistor M4 is turned off. As the third transistor M3 is turned on, the input of the second inverter INV2 at node B is pulled down to ground. Consequently, the output signal OUT is logically low. Moreover, the low logic level at node B turns on the second transistor M2. As the second transistor M2 is turned on, the input of the third inverter INV3 at node A is pulled up to VDD2. As a result, the output signal OUTB is logically low.

In either logic state of the input signal IN, logically low or high, the output signals OUT and OUTB are complementary to each other, resulting in a stable state of the adaptive level shifter 10. With the increasing demand for low-power circuits, however, supply power has been continuously scaled down. In that case, in the logically high state of the input signal IN. VDD1 may be relatively low, for example, 0.3V. As a result, it may be difficult to “strongly” turn on the NMOS transistors M3 and M4 and in turn may be difficult to toggle data stored by the PMOS transistors M1 and M2.

The adaptive level shifter 10 allows the body effect to be present and becomes “adaptive” to VDD1, either high or low, of the input signal IN. Specifically, in the logically high state (logic “1” or VDD1 of the input signal IN, if VDD1 is relatively high, for example, 0.7V, the body effect due to the source to bulk voltage, VDD2−VDD1, in the PMOS transistors M1 and M2 is relatively insignificant. A latch formed by the PMOS transistors M1 and M2 is said to be relatively “strong” and data stored in the latch may be difficult to toggle. In that situation, however, the NMOS transistors M3 and M4 can be “strongly” turned on in response to the relatively high VDD1. As a result, the adaptive level shifter 10 reaches a stable state by the circuit operation as previously discussed. In the adaptive level shifter 10, in response to a first asserted state (relatively high logic-1 state) of the first supply voltage VDD1, the third transistor M3 dominates over the latch, specifically the second transistor M2 of the latch in the present embodiment, in toggling the data. In contrast, in response to a second asserted state (relatively low logic-1 state) of the first supply voltage VDD1, the latch, specifically the second transistor M2 of the latch in the present embodiment, dominates over the third transistor M3 in toggling the data.

Moreover, in the logically high state of the input signal IN, if VDD1 is relatively low, for example, 0.3V, the NMOS transistors M3 and M4 may be “weakly” turned on in response to the relatively low VDD1. In that situation, however, the body effect due to the source to bulk voltage, VDD2−VDD1, in the PMOS transistors M1 and M2 is relatively significant. The latch becomes relatively “weak” and the data stored therein become relatively easy to toggle. As a result, the adaptive level shifter 10 still reaches a stable state by the circuit operation as previously discussed.

In an existing level shifter having the same or similar circuit structure as the level shifter in the adaptive level shifter 10, since the bulk and source terminals of each of the PMOS transistors M1 and M2 are tied to each other, no body effect is present and thus the threshold voltage is not elevated. By comparison, in the logically high state of the input signal IN, if VDD1 is relatively high, the NMOS transistors M3 and M4 are strongly turned on even though the latch is relatively strong. As a result, the existing level shifter reaches a stable state. Nevertheless, in the logically high state of the input signal IN, if VDD1 is relatively low, the latch is strong while the NMOS transistors M1 and M2 may be weakly turned on. As a result, data stored in the latch are difficult to toggle. Therefore, the existing level shifter may not reach a stable state when VDD1 is relatively low in the logically high state.

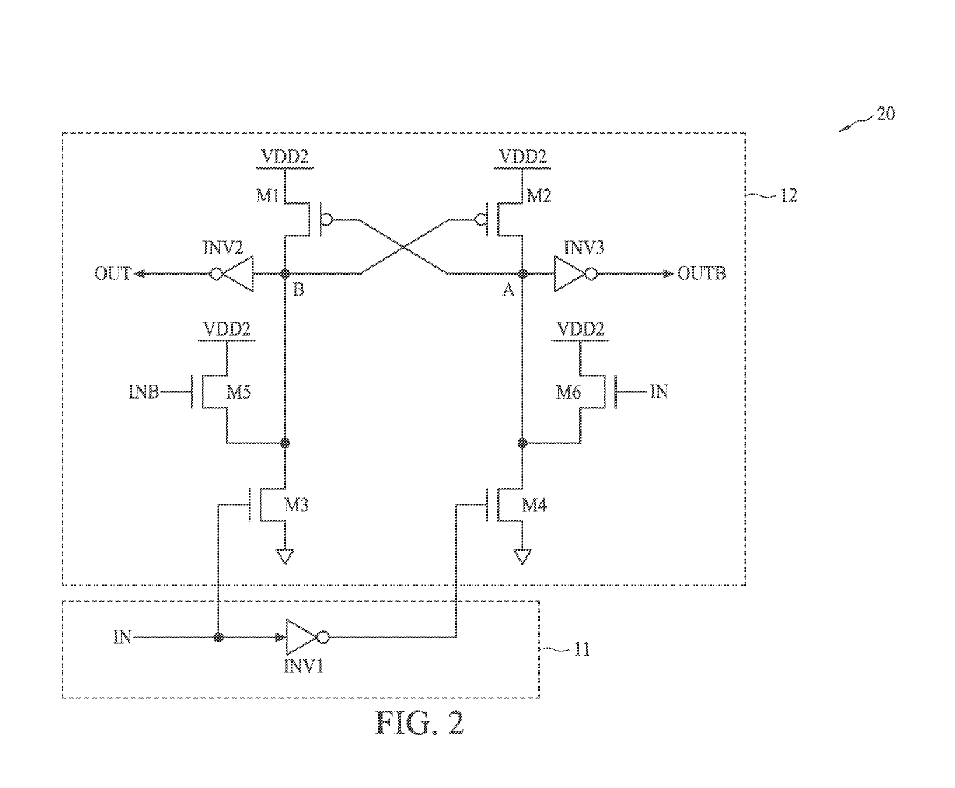

FIG. 2 is a circuit diagram of an adaptive level shifter 20 in accordance with another embodiment. Referring to FIG. 2, the adaptive level shifter 20 is similar to the adaptive level shifter 10 described and illustrated with reference to FIG. 1 except, for example, further comprising NMOS transistors M5 and M6. In the present embodiment, the bulk terminals of the PMOS transistors M1 and M2 are not connected to VDD1 and no body effect is present. In other embodiments, similar to the embodiment in FIG. 1, the bulk terminals of the PMOS transistors M1 and M2 are connected to VDD1. For brevity, such a circuit structure that takes advantage of the body effect is not further illustrated.

With respect to the NMOS transistor M5, a gate terminal receives an input signal INB, which is complementary to the input signal IN in voltage level, a drain terminal connected to VDD2, and a source terminal connected to the drain terminals of the transistors M1 and M3, and also to the input of inverter INV2 and the gate terminal of the transistor M2. As to the NMOS transistor M6, a gate terminal receives the input signal IN, a drain terminal connected to VDD2, and a source terminal connected to the drain terminals of the transistors M2 and M4, and also to the input of inverter INV3 and the gate terminal of the transistor M1.

In operation, in response to a logically low input signal IN, the transistors M3 and M6 are turned off and the transistors M4 and M5 are turned on. As the transistor M4 is turned on while the transistor M6 is turned off, the input of the third inverter INV3 at node A is pulled down to ground. Consequently, the output signal OUTB is logically high, or VDD2. Moreover, the low logic level at node A turns on the transistor M1. As the transistors M1 and M5 are turned on, the input of the second inverter INV2 at node B is pulled up to VDD2. As a result, the output signal OUT is logically low. With the help of the transistor M5, the voltage level at node B can be charged to VDD2 faster than that in the case with the transistor M1 alone.

Further, in response to a logically high input signal IN, the transistors M3 and M6 are turned on and the transistors M4 and M5 are turned off. As the transistor M3 is turned on while the transistor M5 is turned off, the input of the second inverter INV2 at node B is pulled down to ground. Consequently, the output signal OUT is logically high, or VDD2. Moreover, the low logic level at node B turns on the transistor M2. As the transistors M2 and M6 are turned on, the input of the third inverter INV3 at node A is pulled up to VDD2. As a result, the output signal OUTB is logically low. With the help of the transistor M6, the voltage level at node A can be charged to VDD2 faster than that in the case with the transistor M2 alone. The faster charging facilitates the latch to toggle data even when VDD1 of the logically high input signal IN is relatively low.

In either logic state of the input signal IN, logically low or high, the output signals OUT and OUTB are complementary to each other, resulting in a stable state of the adaptive level shifter 20. Moreover, the transistors M5 and M6 facilitate the adaptive level shifter 20 to reach a stable state.

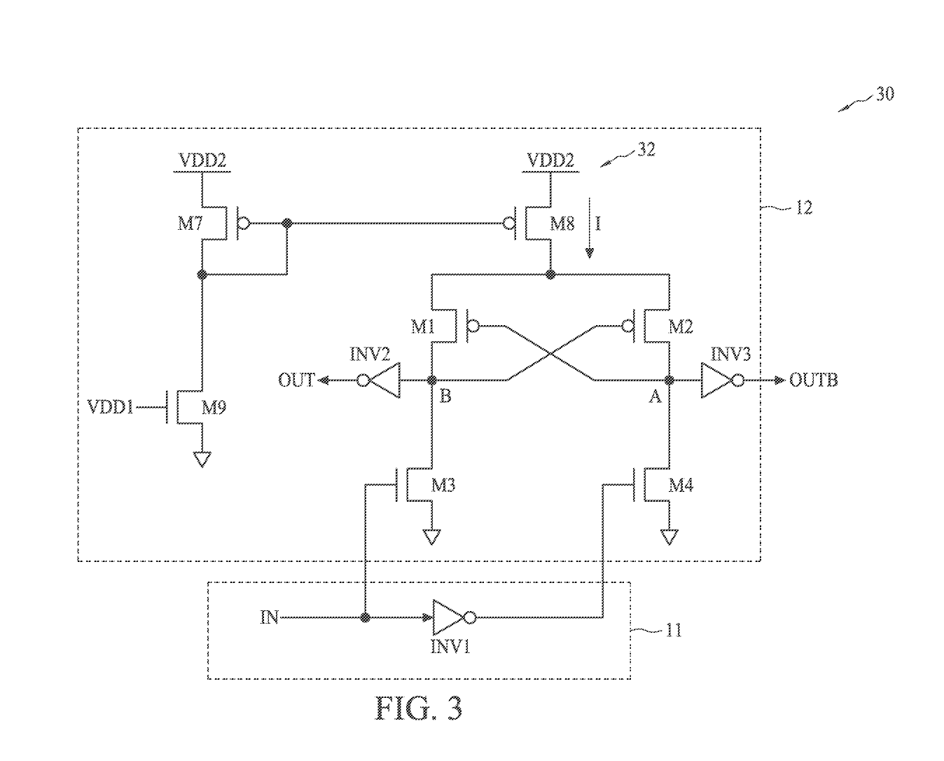

FIG. 3 is a circuit diagram of an adaptive level shifter 30 in accordance with still another embodiment. Referring to FIG. 3, the adaptive level shifter 30 is similar to the adaptive level shifter 10 described and illustrated with reference to FIG. 1 except, for example, further comprising a current mirror 32. The current mirror 32 operates in the second power domain 12. In the present embodiment, the bulk terminals of the PMOS transistors M1 and M2 are not connected to VDD1 and no body effect is present. In another embodiment, similar to the embodiment in FIG. 1, the bulk terminals of the PMOS transistors M1 and M2 are connected to VDD1. For brevity, such a circuit structure that takes advantage of the body effect is not further illustrated. Moreover, in the present embodiment, no pull-up circuits like the transistors M5 and M6 shown in FIG. 2 are employed in the adaptive level shifter 30. In still another embodiment, the transistors M5 and M6 are employed in the adaptive level shifter 30. Such a circuit structure that uses pull-up transistors is not further illustrated. Furthermore, the adaptive level shifter 30 may be configured to include the bulk connection circuit design as shown in FIG. 1 and the pull-up circuit design as shown in FIG. 2.

The current mirror 32 includes PMOS transistors M7, M8 and an NMOS transistor M9. The transistor M7 includes a source terminal connected to VDD2, a drain terminal, and a gate terminal connected to the drain terminal. The transistor M8 includes a source terminal connected to VDD2, a gate terminal connected to the gate terminal of the transistor M7, and a drain terminal connected to the source terminals of the transistors M1 and M2. The transistor M9 includes a drain terminal connected to drain terminal of the transistor M7, and also to the gate terminals of the transistors M7 and M8, a gate terminal connected to VDD1, and a source terminal connected to a reference voltage level.

In operation, in response to the voltage VDD1 at the gate terminal of the transistor M9, a current I is mirrored or copied at the transistor M8, flowing from the source terminal via a channel towards the drain terminal of the transistor M8. By operation of the current mirror 32, the magnitude of the current I is positively correlated with the magnitude of the input voltage VDD1. Accordingly, the current I increases as VDD1 increases, or vice versa. Since the current I flows into the latch formed by the transistors M1 and M2, the latch behavior is dependent on the magnitude of the current I. Specifically, as the current I is large in response to a relatively high VDD1, the latch becomes “strong” and the data stored therein may become difficult to toggle. On the contrary, as the current I is small in response to a relatively low VDD1, the latch becomes “weak” and the data stored therein may become easy to toggle. As previously discussed, when VDD1 is relatively high, the NMOS transistors M3 and M4 can be strongly turned on and toggle the data, even though the latch is strong. Moreover, when VDD1 is relatively low, even though the NMOS transistors M3 and M4 are weakly turned on, the latch is weak and thus the data stored therein becomes easy to toggle. Either way, the adaptive level shifter 30 is adaptive to the change in VDD1 and reaches a stable state.

In the present embodiment, a specific structure of current mirror is employed. However, the present disclosure is not limited to the exemplary current mirror. Other forms or structures of current mirror, which operate in a second power domain and act as a current source that generates a current dependent of a supply voltage in a first power domain, also fall within the contemplated scope of the present disclosure.

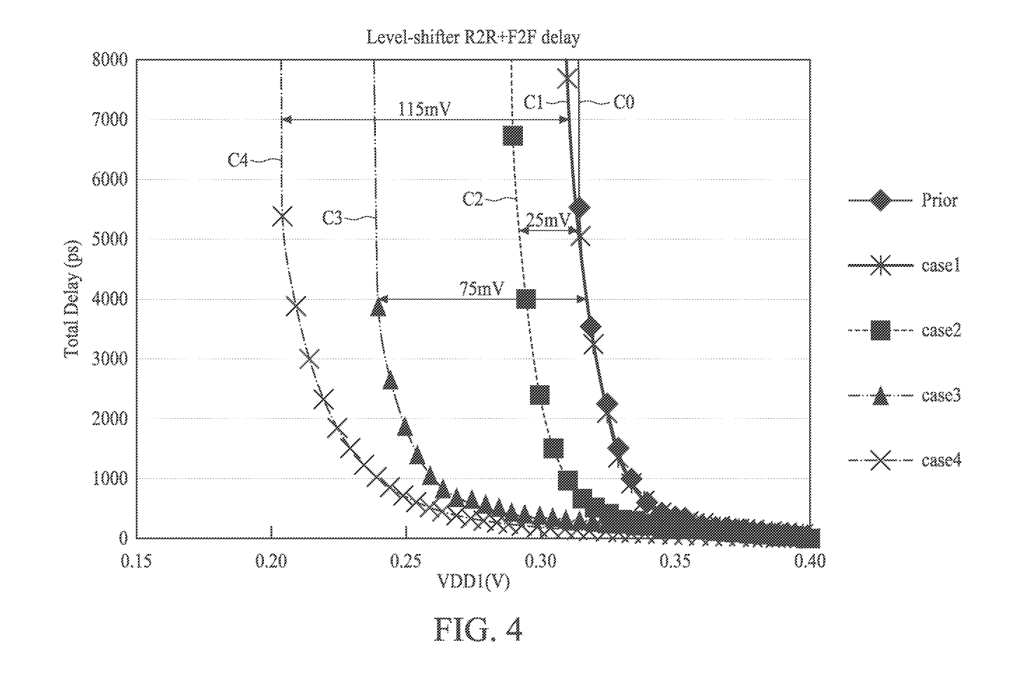

FIG. 4 is a diagram illustrating simulation results. The simulation is conducted at the TT (typical NMOS, typical PMOS) process corner at a temperature of 25 degrees Celsius, given VDD1 being approximately 0.35V and VDD2 approximately 0.825V. Referring to FIG. 4, the lateral axis represents VDD1 in volt, and the vertical axis represents a total delay in picoseconds (ps). In addition, curve C0 represents an existing level shifter, curves C1, C2 and C3 represent the adaptive level shifters 10, 20 and 30 described and illustrated with reference to FIGS. 1, 2, and 3, respectively, and curve C4 represents an adaptive level shifter including the circuit designs of the adaptive level shifters 10, 20 and 30 according to the present disclosure. In the simulation, a rising edge to rising edge (R2R) delay between an input signal and an associated output signal, a falling edge to falling edge (F2F) delay between an input signal and an associated output signal, and a minimum VDD1 that the level shifter under simulation can support are measured. The simulation results are shown in the table below.

| | R2R delay | | F2F delay | | minimum |
|---|---|---|---|---|---|
| TT corner, 25° C., | at VDD1 = | | at VDD1 = | | VDD1 |
| VDD2 = 0.825 V | 0.35 V | | 0.35 V | | (V) |
| existing level shifter (C0) | 108.6 | ps | 158.5 | ps | 0.315 V |
| adaptive level shifter 10 (C1) | 106.7 | ps | 155.6 | ps | 0.310 V |
| adaptive level shifter 20 (C2) | 40.6 | ps | 59.7 | ps | 0.290 V |
| adaptive level shifter 30 (C3) | 25.3 | ps | 78.2 | ps | 0.240 V |
| adaptive level shifter (C4) | 24.3 | ps | 54.1 | ps | 0.200 V |

As illustrated in FIG. 4, it is observed that as the voltage level of VDD1 is lower, the delay is longer. As previously discussed, an NMOS transistor, such as the transistor M3, biased at a relatively low VDD1 is weakly turned on, and thus may be difficult or may take more time to toggle data stored in a latch. In the simulation, it is assumed that a level shifter circuit is not responsive if the delay exceeds half a cycle time.

Regarding the curve C0, the slope approaches infinity and the delay becomes unacceptably high when VDD1 is approximately 0.315V. As a result, the minimum voltage level of VDD1 that the existing level shifter can support is 0.315V.

Likewise, regarding the curves C1, C2 and C3, the minimum voltage levels of VDD1 that the adaptive level shifters 10, 20 and 30 can support are 0.310V, 0.290V and 0.240V, respectively. As compared to the existing level shifter, the R2R and F2F delays in the adaptive level shifters 20 and 30 are significantly decreases. In addition, as compared to the existing level shifter, the adaptive level shifter 20 supports minimum VDD1 of 0.290V or 290 mV, which is 25 mV or 8% lower, and the adaptive level shifter 30 supports minimum VDD1 of 0.240V or 240 mV, which is 75 mV or 23.8% lower. The lower the minimum voltage level of VDD1 a level shifter can support, the more flexible or efficient working range the level shifter can operate between different power domains.

As to the curve C4, which integrates the circuit designs of the adaptive level shifters 10, 20 and 30, the R2R and F2F delays are significantly decreased, and the minimum VDD1 reaches as low as 0.200V or 200 mV, which is 115 mV or 36.5% lower, as compared to the existing level shifter.

In some embodiments, the present disclosure provides a level shifter for operating between a first power domain under a first supply voltage and a second power domain under a second supply voltage. The level shifter includes a latch configured to store data and operate in the second power domain. The latch includes a first transistor including a bulk terminal to receive the first supply voltage, the first supply being different from the second supply voltage, and includes a second transistor including a bulk terminal to receive the first supply voltage. The level shifter further includes a third transistor configured to be biased at the first supply voltage. In response to a first asserted state of the first supply voltage, the third transistor dominates over the latch in toggling the data and, in response to a second asserted state of the first supply voltage, the latch dominates over the third transistor in toggling the data. The second asserted state is lower in voltage level than the first asserted state.

In some embodiments, the present disclosure also provides a level shifter for operating between a first power domain under a first supply voltage and a second power domain under a second supply voltage. The level shifter includes a latch configured to operate in the second power domain. The latch includes a first transistor and a second transistor. The level shifter further includes a third transistor configured to operate in the second power domain and receive an input signal from the first power domain, and includes a fourth transistor configured to operate in the second domain and receive a signal complementary to the input signal. The first, third and fourth transistors are connected to a first node. The fourth transistor is configured to charge the first node to the second supply voltage in response to a first state of the input signal.

In some embodiments, the present disclosure provides a level shifter for operating between a first power domain under a first supply voltage and a second power domain under a second supply voltage. The level shifter includes a latch, formed by a first transistor and a second transistor, configured to store data and operate in the second power domain. The level shifter further includes a third transistor configured to be biased at the first supply voltage, and a current source configured to generate a current in response to the first supply voltage. The current flows towards the latch, and the magnitude of the current is positively correlated with the first supply voltage. In response to a first asserted state of the first supply voltage, the third transistor dominates over the current source in toggling the data and, in response to a second asserted state of the first supply voltage, the current source dominates over the third transistor in toggling the data. The second asserted state is lower in voltage level than the first asserted state.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A level shifter for operating between a first power domain under a first supply voltage and a second power domain under a second supply voltage, the level shifter comprising:
a latch configured to store data and operate in the second power domain, the latch including:
a first transistor including a bulk terminal to receive the first supply voltage, the first supply being different from the second supply voltage; and
a second transistor including a bulk terminal to receive the first supply voltage; and
a third transistor configured to be biased at the first supply voltage,
wherein, in response to a first asserted state of the first supply voltage, the third transistor dominates over the latch in toggling the data and, in response to a second asserted state of the first supply voltage, the latch dominates over the third transistor in toggling the data, the second asserted state being lower in voltage level than the first asserted state.

2. The level shifter according to claim 1, wherein the first transistor further includes a source terminal to receive the second supply voltage, a gate terminal, and a drain terminal, and the second transistor further includes a source terminal to receive the second supply voltage, a gate terminal connected to the drain terminal of the first transistor, and a drain terminal connected to the gate terminal of the first transistor.

3. The level shifter according to claim 2, wherein the third transistor includes a drain terminal connected to the drain terminal of the first transistor, and a gate terminal to receive an input signal from the first power domain.

4. The level shifter according to claim 3 further comprising a fourth transistor, wherein the fourth transistor includes a drain terminal connected to the drain terminal of the second transistor, and a gate terminal to receive a signal complementary to the input signal.

5. The level shifter according to claim 1, wherein the first supply voltage is lower than the second supply voltage.

6. A level shifter for operating between a first power domain under a first supply voltage and a second power domain under a second supply voltage, the level shifter comprising:
a latch configured to operate in the second power domain, the latch including a first transistor and a second transistor;
a third transistor configured to operate in the second power domain and receive an input signal from the first power domain; and
a fourth transistor configured to operate in the second domain and receive a signal complementary to the input signal, the first, third and fourth transistors being connected to a first node, wherein the fourth transistor is configured to charge the first node to the second supply voltage in response to a first state of the input signal.

7. The level shifter according to claim 6, wherein the first transistor includes a source terminal to receive the second supply voltage, and a drain terminal connected to the first node, the first transistor configured to charge the first node to the second supply voltage in response to the first state of the input signal.

8. The level shifter according to claim 6, wherein the fourth transistor includes a drain terminal to receive the second supply voltage, and a source terminal connected to the first node.

9. The level shifter according to claim 6 further comprising:
a fifth transistor configured to operate in the second power domain and receive the signal complementary to the input signal; and
a sixth transistor configured to operate in the second domain and receive the input signal, the second, fifth and sixth transistors being connected to a second node, wherein the sixth transistor is configured to charge the second node to the second supply voltage in response to a second state of the input signal.

10. The level shifter according to claim 9, wherein the second transistor includes a source terminal to receive the second supply voltage, and a drain terminal connected to the second node, the second transistor configured to charge the second node to the second supply voltage in response to the second state of the input signal.

11. The level shifter according to claim 9, wherein the sixth transistor includes a drain terminal to receive the second supply voltage, and a source terminal connected to the second node.

12. (canceled)

13. A level shifter for operating between a first power domain under a first supply voltage and a second power domain under a second supply voltage, the level shifter comprising:
a latch configured to store data and operate in the second power domain, the latch including a first transistor and a second transistor;
a third transistor configured to be biased at the first supply voltage; and
a current source configured to generate a current in response to the first supply voltage, the current flowing towards the latch, and the magnitude of the current being positively correlated with the first supply voltage,
wherein, in response to a first asserted state of the first supply voltage, the third transistor dominates over the current source in toggling the data and, in response to a second asserted state of the first supply voltage, the current source dominates over the third transistor in toggling the data, the second asserted state being lower in voltage level than the first asserted state,
wherein the first transistor includes a bulk terminal to receive the first supply voltage, and the second transistor includes a bulk terminal to receive the first supply voltage.

14. The level shifter according to claim 13, wherein the current source includes a current mirror configured to operate in the second power domain.

15. The level shifter according to claim 14, wherein the current mirror includes a transistor including a gate terminal biased at the first supply voltage.

16. (canceled)

17. The level shifter according to claim 13, wherein the third transistor is configured to receive an input signal from the first power domain, further comprising:
a fourth transistor configured to operate in the second domain and receive a signal complementary to the input signal, the first, third and fourth transistors being connected to a first node, wherein the fourth transistor is configured to charge the first node to the second supply voltage in response to a first state of the input signal.

18. The level shifter according to claim 17, wherein the first transistor includes a source terminal to receive the second supply voltage, and a drain terminal connected to the first node, the first transistor configured to charge the first node to the second supply voltage in response to the first state of the input signal.

19. The level shifter according to claim 17 further comprising:
a fifth transistor configured to receive the signal complementary to the input signal; and
a sixth transistor configured to operate in the second domain and receive the input signal, the second, fifth and sixth transistors being connected to a second node, wherein the sixth transistor is configured to charge the second node to the second supply voltage in response to a second state of the input signal.

20. The level shifter according to claim 19, wherein the second transistor includes a source terminal to receive the second supply voltage, and a drain terminal connected to the second node, the second transistor configured to charge the second node to the second supply voltage in response to the second state of the input signal.
